(19) United States
(12) Patent Application Publication
(10) Pub. No.: US 2014/0185830 A1
(43) Pub. Date: Jul. 3, 2014

(54) METHODS, SYSTEMS, AND APPARATUS FOR AUDIO BACKTRACKING CONTROL

(71) Applicant: Daniel Avrahami, Mountain View, CA (US)

(72) Inventor: Daniel Avrahami, Mountain View, CA (US)

(21) Appl. No.: 13/728,505

(22) Filed: Dec. 27, 2012

(51) Int. Cl. H03G 3/20

(52) U.S. Cl. CPC H03G 3/20
USPC 381/107

(57) ABSTRACT

Example methods, systems, and apparatus for audio backtracking control are provided. An example method includes comparing an audio input value associated with an audio input to a threshold. The audio input is to be synchronized with an audio backtrack. The example method includes suppressing an output of the audio backtrack when the audio input value is below the threshold. The example method includes controlling a temporal pointer associated with the audio backtrack during a period of time in which the audio input value is below the threshold.

### FIELD OF THE DISCLOSURE

The present disclosure relates generally to audio backtracking and, more particularly, to methods, systems and apparatus for audio backtracking control.

### BACKGROUND

Lip-synching or miming is a common practice in live performances (e.g., live musical performances). To lip-synch, a performer will act as though he or she is singing a particular number while a pre-recorded audio track (e.g., an audio backtrack) of the particular number (e.g., including singing) is played. The performer attempts to match his or her movements (e.g., facial or mouth movements) to the audio backtrack to give an audience the perception that the performer is actually singing the audio that is being heard by the audience.

### BRIEF DESCRIPTION OF THE DRAWINGS

FIG. 1 illustrates an example system implemented in accordance with the teachings of this disclosure to control audio backtracking.

FIG. 2 is an illustration of example audio outputs according to a mute setting implemented by an example audio controller of FIG. 1.

FIG. 3 is an illustration of example audio outputs according to a pause setting implemented by the example audio controller of FIG. 1.

FIG. 4 is an illustration of an example implementation of the example audio controller of FIG. 1.

FIG. 5 is a flowchart representative of example machine readable instructions that may be executed to implement the example audio controller of FIGS. 1 and 4.

FIG. 6 is another flowchart representative of example machine readable instructions that may be executed to implement the example audio controller of FIGS. 1 and 4.

FIG. 7 is a schematic illustration of an example processing platform that may execute the example machine readable instructions of FIGS. 5 and/or 6 to implement the example audio controller of FIGS. 1 and 4.

### DETAILED DESCRIPTION

Lip-synching, in which a performer attempts to sing in a synchronized manner with an audio backtrack, may be beneficial where the performer wishes to perform a live dance number as part of the live performance, but may be unable to sing at a performance level and/or to continuously sing while performing the dance number. Lip-synching may also be beneficial where a performer is ill or other issues arise during the live performance.

Although lip-synching aids the performer during the performance, it is often undesirable for the audience to be made aware of the lip-synching. Thus, one or more attempts to hide the use of audio backtracks from the audience may be performed. However, it may be difficult to hide the use of the audio backtracks when movements and/or singing by the performer does not match an audio backtrack. For example, the performer may stop acting as though he or she is singing while the audio backtrack continues to play, revealing the lip-synching to the audience.

Example methods, systems, apparatus, and/or articles of manufacture disclosed herein provide control over audio backtracking to reduce (e.g., minimize) audience perception of the audio backtracking. Examples disclosed herein analyze audio output by a performer (e.g., voice or vocal input) and determine how corresponding audio backtracking is to be output based on the analysis. In some examples, a performer may stop singing or stop singing at a sufficiently audible level and examples disclosed herein lower the volume of the audio backtracking (e.g., so that the audio backtracking is inaudible). In such examples, the audio backtracking continues at the lowered volume. The audio backtracking may remain at the lowered volume until the performer begins singing again. In other examples, a performer may stop singing and the examples disclosed herein pause the audio backtracking (e.g., so that the audio backtracking does not continue), which reduces (e.g., prevents and/or minimizes) the possibility of the audio backtracking from being heard by an audience when the performer stops performing. When the performer begins to sing again, the audio backtracking may begin playing again.

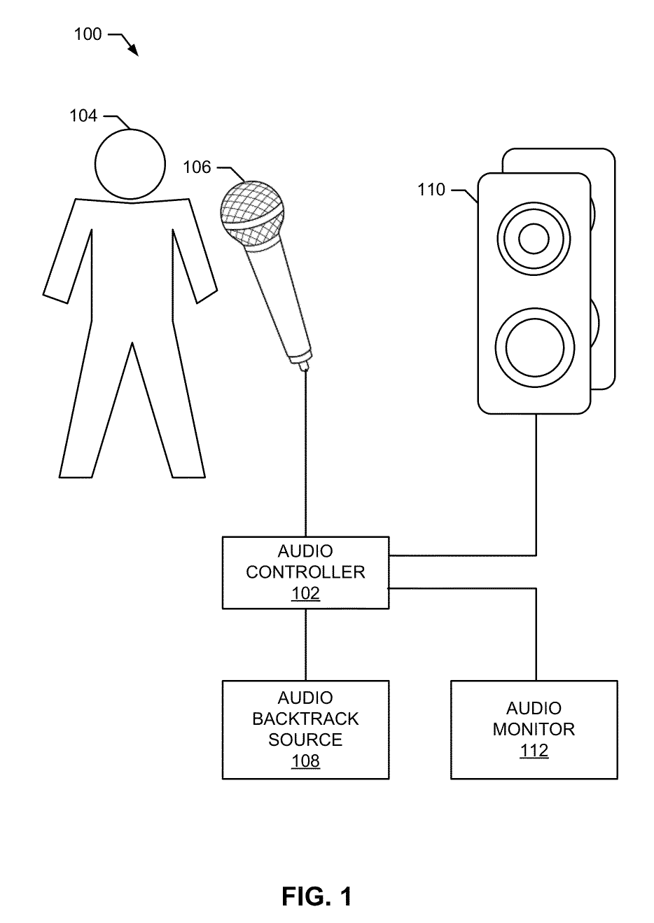

FIG. 1 illustrates an example system 100 including an example audio controller 102 implemented in accordance with the teachings of this disclosure to control audio backtracking. The example audio controller 102 provides control over audio backtracking to reduce (e.g., minimize) audience perception of the audio backtracking. The example audio controller 102 of FIG. 1 analyzes audio output by a performer 104 via an input 106 (e.g., a microphone) and determines how audio backtracking from an audio backtrack source 108 is to be presented via an output 110 (e.g., speakers) based on the analysis.

During a performance, the performer 104 vocalizes (e.g., sings and/or speaks) into the microphone 106. The vocal input is passed from the example microphone 106 to the audio controller 102 to be transmitted (e.g., played) to the output 110 in conjunction with a corresponding audio backtrack provided by the audio backtrack source 108. For example, the performer 104 may sing a particular song. A corresponding audio backtrack is a prerecorded version of the same song (e.g., vocals prerecorded by the performer 104). One or more audio backtracks may correspond to a particular vocal input or a portion of a song. For example, one audio backtrack may correspond to vocals of a song and another audio backtrack may correspond to an instrumental accompaniment for the song. The example audio backtrack source 108 stores one or more audio backtracks for a performance. The one or more audio backtracks may be stored on a memory as .wav files, mp3 files, etc. The one or more audio backtracks may be stored in a playlist (e.g., set by the performer 104), for example.

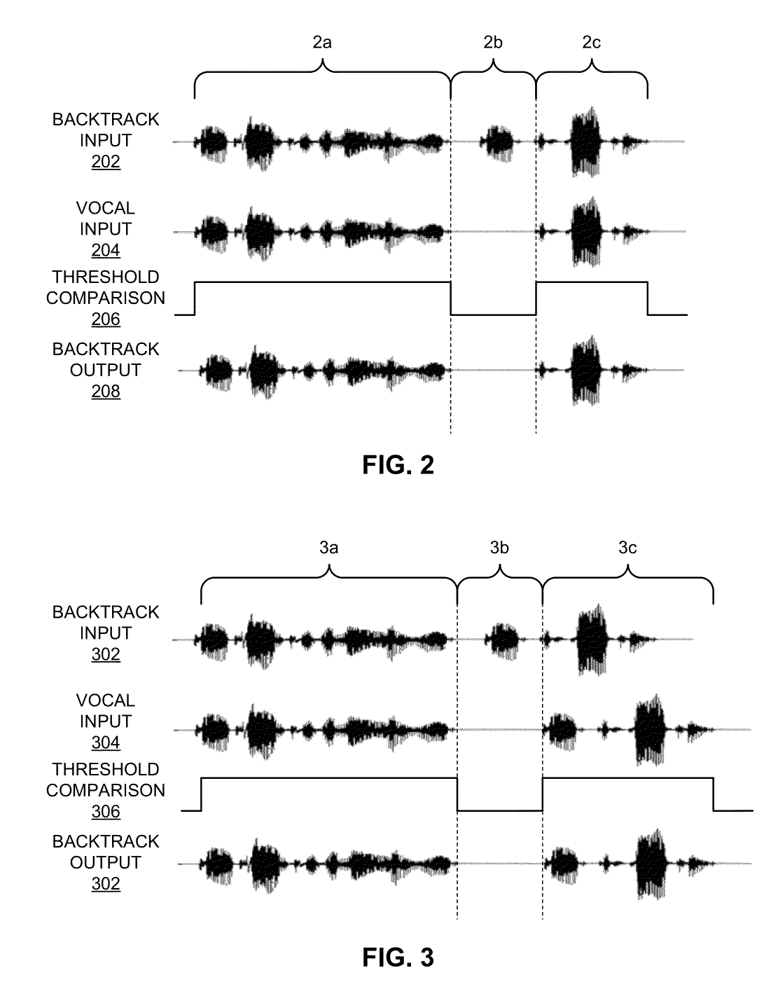

The audio controller 102 of the illustrated example of FIG. 1 implements one or more settings to control a manner in which audio backtracking (e.g., a prerecorded vocal backtrack) from the audio backtrack source 108 is output via the speakers 110 in conjunction with the vocal input from the performer 104. In some example settings (e.g., a mute setting), if the performer 104 forgets and/or otherwise fails to sing a word or phrase, the audio controller 102 prevents the audio backtrack from producing its corresponding sound via the output 110 (e.g., speakers). To prevent the audio backtrack from producing its corresponding sound, the example audio controller 102 suppresses an output of the audio backtrack. For example, if the performer 104 stops singing or stops singing at a sufficiently audible level, to manipulate the audio backtrack, the audio controller 102 lowers the volume of the audio backtrack so that the audio backtrack is inaudible, but allows the audio backtrack to continue to progress (e.g., play). In an example mute setting, the audio controller 102 leaves the audio backtrack at the lowered volume level until the performer 104 begins singing or begins singing at a sufficiently audible level again (e.g., after a threshold decibel level and/or energy level is detected). An example of audio backtrack output during the example mute setting is illustrated in connection with FIG. 2, as described in further detail below.

In another example setting (e.g., a pause setting), if the performer 104 stops singing or stops singing at a sufficiently audible level, to manipulate the audio backtrack, the audio controller 102 pauses the audio backtrack so that the audio backtrack does not progress (e.g., play). To pause the audio backtrack so that the audio backtrack does not progress, the audio controller 102 controls a temporal pointer associated with the audio backtrack. In this setting, the audio controller 102 prevents the audio backtrack from progressing or advancing (e.g., the audio backtrack is paused or stopped) until the performer 104 begins singing or begins singing at a sufficiently audible level again (e.g., after a threshold decibel level and/or energy level is detected). In contrast to the example mute setting which mutes the volume of the audio backtrack, but allows the audio backtrack to advance, the example pause setting stops the audio backtrack from progressing. For example, in the mute setting, the audio controller 102 allows a temporal pointer associated with the audio backtrack to progress, while in the example pause setting, the audio controller 102 controls (e.g., stops) the temporal pointer associated with the audio backtrack. The example pause setting may be useful when, for example, the performer 104 is learning a particular song and is unfamiliar with the lyrics. An example of audio backtrack output during the example pause setting is illustrated in connection with FIG. 3, as described in further detail below. The particular setting to be implemented by the example audio controller 102 may be selected by the performer 104 and/or another user.

The audio controller 102 of the illustrated example of FIG. 1 outputs both the vocal input from the performer 104 and the audio backtrack from the audio backtrack source 108 via the example speakers 110. Outputting both the vocal input from the performer 104 and the audio backtrack allows the performer 104 to be heard (e.g., the performer 104 may include “shout-outs” to the audience that may be heard by the audience). Any number of speakers 110 and/or other outputs may be used to output the vocals and/or audio backtrack. In some examples, the vocal input is passed directly from the microphone 106 to the speakers 110 for output (e.g., playing) and the vocal input is passed to the audio controller 102 for analysis in determining how to output the audio backtrack. In other examples, the audio input from the performer 104 is not output by the speakers 110, but instead is used only to control the output of the audio backtracks. The audio input from the performer 104 may not be output by the speakers 110 when, for example, the performer 104 is ill and/or the performer 104 forgets song lyrics.

The example audio monitor 112 of FIG. 1 may be used to output an indication of when the example audio controller 102 is manipulating audio backtracks. The example audio monitor 112 may be used by a user (e.g., a producer of a performance, a sound engineer, etc.) to alter a presentation of the performance based on whether the audio controller 102 is manipulating the audio backtracks. For example, the audio monitor 112 may output an indication that the example audio controller 102 has muted and/or paused an audio backtrack to allow the producer to present a commercial and/or to show a video feed from a different camera (e.g., to cut away from video of the performer 104 and to video of the audience) during a television broadcast. By presenting an indication that the example audio controller 102 is manipulating audio backtracks, the example audio monitor 112 enables a user to take actions in an attempt to further reduce (e.g., minimize) an audience perception that the performer 104 is not singing.

In some examples, when the audio monitor 112 determines that the example audio controller 102 is manipulating audio backtracks, the audio monitor 112 generates a control signal to cause a camera to activate (e.g., to cause a particular camera video feed to be broadcast). In other examples, when the audio monitor 112 determines that the example audio controller 102 is manipulating audio backtracks, the audio monitor 112 generates a control signal to cause a commercial to be broadcast.

While the illustrated example refers to the performer 104 singing, examples disclosed herein may be implemented with other types of input such as instrumental input, vocal input, speech input, digital input, etc.

FIG. 2 is an illustration of example audio outputs according to an example mute setting implemented by the example audio controller 102 of FIG. 1. The example audio controller 102 implements one or more different settings to control how audio backtracking from the audio backtrack source 108 of FIG. 1 is output via the example speakers 110 in conjunction with the vocal input from the performer 104. In the mute setting of the illustrated example of FIG. 2, if the performer 104 does not sing a word or phrase (e.g., the performer 104 forgets to sing), the audio backtracking will not sound. The example controller 102 may determine that the performer 104 did not sing a word or phrase by comparing an input audio power level and/or energy level (e.g., a decibel power measurement, frequency measurement, etc.) to one or more threshold values. To prevent the audio backtrack from sounding, the example audio controller 102 suppresses an output of the audio backtrack. For example, if the performer 104 stops singing or stops singing at a sufficiently audible level (e.g., a power ratio threshold in decibels, an energy threshold, etc.), the audio controller 102 lowers the volume of the audio backtrack so that the audio backtrack is inaudible, but allows the audio backtrack to continue to progress (e.g., play). In this setting, the example audio controller 102 leaves the audio backtrack at the lowered volume level until the performer 104 begins singing or begins singing at a sufficiently audible level again.

An audio backtrack input 202 of the illustrated example of FIG. 2 reflects an example audio backtrack (e.g., a prerecorded audio signal) stored at the audio backtrack source 108. The example audio backtrack input 202 is passed from the audio backtrack source 108 to the audio controller 102 to be output (e.g., via the speakers 110). A vocal input 204 of the illustrated example of FIG. 2 shows an audio signal collected by the input 106 (e.g., microphone) from the performer 104. The example vocal input 204 is passed from the example microphone 106 to the example audio controller 102. The example audio controller 102 manipulates the example audio backtrack input 202 to match the vocal input 204 to be output via the example speakers 110 as an audio backtrack output 208.

To determine how the audio backtrack input 202 is to be manipulated and output as the audio backtrack output 208, the example audio controller 102 of FIG. 2 compares the vocal input 204 to a threshold. The threshold specifies a particular level (e.g., an energy level, a decibel level) to be met or exceeded by the vocal input 204 to allow audio backtracking to be played as normal, without manipulation (e.g., without being muted or without being paused). In this way, small sounds (e.g., labored breathing) will not trigger playing of the audio backtrack. In the illustrated example of FIG. 2, an output 206 for the threshold comparison is high when the vocal input 204 exceeds the threshold and is low when the vocal input 204 does not exceed the threshold. The example audio backtrack output 208 shows how the audio backtracking of the audio backtrack input 202 is output via the speakers 110 based on the threshold comparison performed by the audio controller 102.

In the illustrated example of FIG. 2, the performer 104 sings (e.g., shown in section 2a of the vocal input 204), stops singing (e.g., shown in section 2b of the vocal input 204), and starts singing again (e.g., shown in section 2c of the vocal input 204). The audio controller 102 determines how to output the audio backtrack input 202 when the performer 104 stops singing in section 2b and starts singing in section 2c.

In section 2a of the illustrated example, the threshold comparison 206 is high because the vocal input 204 exceeds the threshold. The audio controller 102 does not manipulate the audio backtrack input 202 because the vocal input 204 exceeds the threshold. Thus, to match the vocal input 204 of section 2a, the audio backtrack output 208 is an unmanipulated version of the audio backtrack input 202 (e.g., is played normally as at a sufficiently audible volume).

In section 2b of the illustrated example, the threshold comparison 206 is low because the vocal input 204 does not exceed the threshold. In the illustrated example of FIG. 2, the audio controller 102 manipulates the audio backtrack input 202 by lowering the volume of the audio backtrack input 202 (e.g., muting the audio backtrack input 202) while allowing the audio backtracking to progress (e.g., play) when the vocal input 204 does not exceed the threshold. To match the vocal input 204, the audio controller 102 mutes the audio backtrack input 202 to create the audio backtrack output 208 of section 2b.

In section 2c of the illustrated example, the threshold comparison 206 is high because the vocal input 204 exceeds the threshold. To match the vocal input 204 of section 2c, the audio controller 102 manipulates the audio backtrack input 202 by increasing the volume of the audio backtrack input 202 when the vocal input 204 exceeds the threshold to create the audio backtrack output 208 of section 2c. For example, the audio controller 102 stops muting the audio backtrack input 202 when the vocal input 204 exceeds the threshold. Because the example audio controller 102 muted the audio backtrack input 202, but allowed it to advance during the muted duration, the performer 104 is granted an opportunity to resume a presentation without having to repeat what may be been missed from the backtrack input sequence 202.

As shown in the illustrated example of FIG. 2, if the performer 104 stops singing or stops singing at a sufficiently audible level (e.g., at section 2b), the audio controller 102 mutes the audio backtrack input 202, but allows the audio backtrack input 202 to continue to progress (e.g., play). The example audio controller 102 leaves the audio backtrack muted until the performer 104 resumes singing or begins singing at a sufficiently audible level again (e.g., at section 2c).

FIG. 3 is an illustration of example audio outputs according to an example pause setting implemented by the example audio controller 102 of FIG. 1. Unlike the example mute setting, in the example pause setting, if the performer 104 stops singing or stops singing at a sufficiently audible level, the audio controller 102 pauses the audio backtrack so that the audio backtrack does not progress (e.g., the audio backtrack does not play). To pause the audio backtrack so that the audio backtrack does not progress, the audio controller 102 controls (e.g., stops) a temporal pointer associated with the audio backtrack. In this setting, the audio controller 102 prevents the audio backtrack from progressing (e.g., the audio backtrack is paused or stopped) until the performer 104 begins singing or begins singing at a sufficiently audible level again.

An audio backtrack input 302 of the illustrated example of FIG. 3 (e.g., similar to the audio backtrack input 202 of FIG. 2) shows an example audio backtrack that is stored at the audio backtrack source 108 and is passed from the audio backtrack source 108 to the audio controller 102 to be output via the speakers 110. A vocal input 304 of the illustrated example of FIG. 3 (e.g., similar to the vocal input 204 of FIG. 2) shows an example audio signal collected by the microphone 106 from the performer 104 that is passed from the microphone 106 to the audio controller 102. The audio controller 102 manipulates the audio backtrack input 302 to match the vocal input 304 to be output via the speakers 110 as an audio backtrack output 308.

To determine how the audio backtrack input 302 is to be manipulated and output as the audio backtrack output 308, the example audio controller 102 compares the vocal input 304 to a threshold that specifies a particular energy level to be met or exceeded by the vocal input 204 to allow audio backtracking to be played as normal, without manipulation (e.g., without being muted or without being paused). In the illustrated example of FIG. 3, a threshold comparison 306 (e.g., similar to the threshold comparison 206 of FIG. 2) is high when the vocal input 304 exceeds the threshold and is low when the vocal input 304 does not exceed the threshold. The audio backtrack output 308 shows how the audio backtracking of the audio backtrack input 302 is output via the speakers 110 based on the threshold comparison performed by the audio controller 102.

In the illustrated example of FIG. 3, the performer 104 sings (e.g., shown in section 3a of the vocal input 304), stops singing (e.g., shown in section 3b of the vocal input 304), and starts singing again (e.g., shown in section 3c of the vocal input 304). The audio controller 102 determines how to output the audio backtrack input 302 when the performer 104 stops singing in section 3b and starts singing in section 3c.

In section 3a of the illustrated example of FIG. 3, the threshold comparison 306 is high because the vocal input 304 exceeds the threshold. The audio controller 102 does not manipulate the audio backtrack input 302 because the vocal input 304 exceeds the threshold. Thus, to match the vocal input 304 of section 3a, the audio backtrack output 308 is an unmanipulated version of the audio backtrack input 302 (e.g., is played normally at a sufficiently audible volume).

In section 3b of the illustrated example of FIG. 3, the threshold comparison 306 is low because the vocal input 304 does not exceed the threshold. The example audio controller 102 manipulates the audio backtrack input 302 by pausing the audio backtrack input 302 when the vocal input 304 does not exceed the threshold. To match the vocal input 304, the audio controller 102 pauses the audio backtrack input 302 to create the audio backtrack output 308 of section 3b.

In section 3c of the illustrated example of FIG. 3, the threshold comparison 306 is high because the vocal input 304 exceeds the threshold. To match the example vocal input 304 of section 3c, the example audio controller 102 manipulates the example audio backtrack input 302 by resuming (e.g., unpausing and/or playing) the audio backtrack input 302 when the vocal input 304 exceeds the example threshold to create the audio backtrack output 308 of section 3c. For example, the audio controller 102 resumes playing the audio backtrack input 302 when the vocal input 304 exceeds the threshold.

As shown in the illustrated example of FIG. 3, if the performer 104 stops singing or stops singing at a sufficiently audible level (e.g., at section 3b), the audio controller 102 pauses the audio backtrack input 302. The example audio controller 102 leaves the audio backtrack paused until the performer 104 begins singing or begins singing at a sufficiently audible level again (e.g., at section 3c).

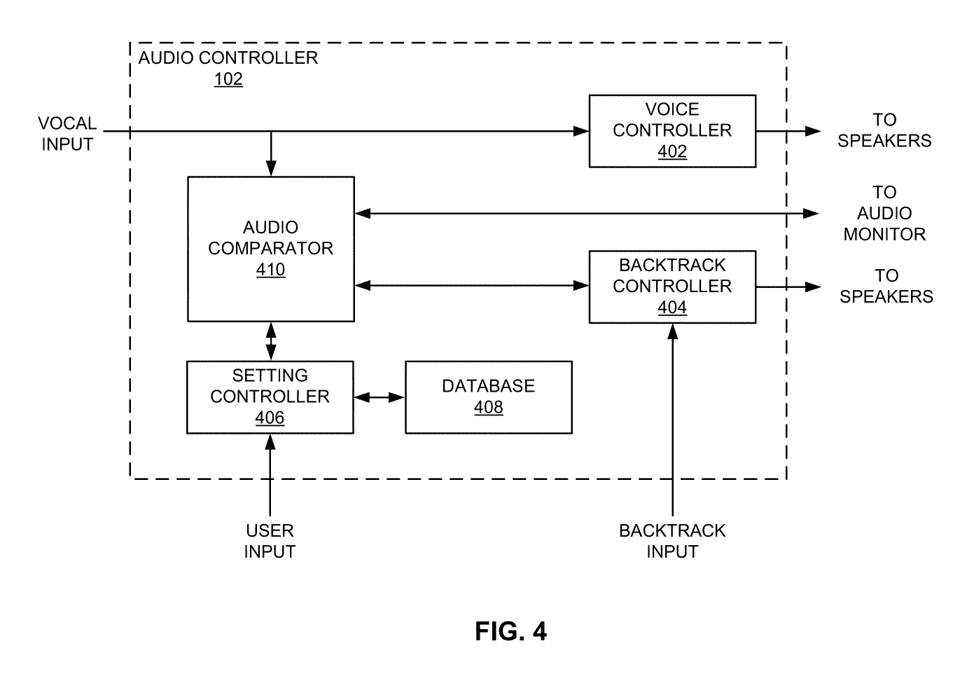

FIG. 4 is an illustration of an example implementation of the example audio controller 102 of FIG. 1. The example audio controller 102 analyzes audio output by a performer (e.g., the performer 104 of FIG. 1) via an input 106 (e.g., the microphone of FIG. 1) and determines how audio backtracking from an audio backtrack source (e.g., the audio backtrack source 108) is to be output via an output 110 (e.g., the speakers) based on the analysis. The audio controller 102 of the illustrated example includes an example voice controller 402, an example audio backtrack controller 404, an example setting controller 406, an example database 408, and an example audio comparator 410.

The example voice controller 402 of FIG. 4 receives vocal input (e.g., vocals) from the performer 104 via the microphone 106 and outputs the vocals via the speakers 110. The example audio backtrack controller 404 of FIG. 4 receives audio backtracks from the audio backtrack source 108 and outputs the audio backtracks via the speakers 110. The audio backtrack controller 404 may manipulate the audio backtracks prior to outputting the audio backtracks based on instructions received from the audio comparator 410. Manipulating the audio backtracks enables one or more output audio backtracks to match the corresponding vocals.

The example setting controller 406 of FIG. 4 is used to control the setting implemented by the audio controller 102 when determining how an audio backtrack is to be output in conjunction with a vocal input from the performer 104. In an example mute setting, if the performer 104 stops singing or stops singing at a sufficiently audible level, to manipulate the audio backtrack, the audio controller 102 lowers the volume of the audio backtrack so that the audio backtrack is inaudible, but allows the audio backtrack to continue to progress (e.g., play) and/or otherwise advance through its temporal sequence. On the other hand, in an example pause setting, if the performer 104 stops singing or stops singing at a sufficiently audible level, to manipulate the audio backtrack, the audio controller 102 pauses the audio backtrack so that the audio backtrack does not progress (e.g., the audio backtrack does not play). To pause the audio backtrack so that the audio backtrack does not progress, the audio controller 102 controls (e.g., stops) a temporal pointer associated with the audio backtrack.

One or more thresholds may be used to define one or more audible levels of vocal input from the performer 104 for each of the settings. The performer 104 and/or another user selects the setting(s) and/or threshold(s) to be implemented by the example setting controller 406. The one or more thresholds and/or settings (e.g., rules associated with each of the settings) may be stored in the database 408 of the illustrated example of FIG. 4.

The example audio comparator 410 of FIG. 4 receives vocal input from the performer 104 via the microphone 106. The example audio comparator 410 compares the vocal input to one or more thresholds provided by the example setting controller 406 in accordance with the particular setting selected by the performer 104, other user, and/or one or more settings profile(s) stored in the example database 408 (e.g., a default profile). The example threshold specifies one or more energy level(s) to be met or exceeded by the vocal input to allow audio backtracking to be played as normal, without manipulation (e.g., without being played at a low volume or being paused). In some examples, if the audio comparator 410 determines that an energy level of the vocal input exceeds the threshold, the audio comparator 410 instructs the audio backtrack controller 404 to output the audio backtrack without manipulation. In some examples, if the audio comparator 410 determines that the energy level of the vocal input does not exceed the threshold, the audio comparator 410 instructs the audio backtrack controller 404 to manipulate the audio backtrack according to the setting provided by the setting controller 406 prior to outputting the audio backtrack. The example audio comparator 410 compares the vocal input to the threshold periodically (e.g., every one hundred milliseconds), aperiodically, on a scheduled basis, and/or on a manual basis.

In the example mute setting, to prevent the audio backtrack from producing its corresponding sound, the audio controller 102 suppresses an output of the audio backtrack. For example, if the audio comparator 410 determines that the energy level of the vocal input does not exceed the threshold, the audio comparator 410 instructs the audio backtrack controller 404 to mute the volume of the audio backtrack, while allowing the audio backtrack to continue playing (e.g., continue outputting the audio backtrack). When muting the volume of the audio backtrack, the example audio backtrack controller 404 of FIG. 4 may apply a rate of decay for the volume of the audio backtrack (e.g., quickly fade out the audio backtrack to zero, gently fade out the audio backtrack to zero, etc.). In the example pause setting, if the example audio comparator 410 determines that the energy level of the vocal input does not exceed the threshold, the audio comparator 410 instructs the example audio backtrack controller 404 to pause the audio backtrack (e.g., to stop outputting the audio backtrack). To pause the audio backtrack so that the audio backtrack does not progress, the audio backtrack controller 404 controls (e.g., stops) a temporal pointer associated with the audio backtrack. When pausing the audio backtrack, the example audio backtrack controller 404 may sustain the audio backtrack for a period of time (e.g., for 500 milliseconds) and then fade the volume of the audio backtrack to an audio level (e.g., to zero) to avoid an abrupt cutoff to the audio backtrack.

If the example audio comparator 410 determines that the energy level of the vocal input exceeds the threshold, the audio comparator 410 instructs the audio backtrack controller 404 to return to playing the audio backtrack as normal. In the example mute setting, if the example audio comparator 410 determines that the energy level of the vocal input exceeds the threshold, the audio comparator 410 instructs the audio backtrack controller 404 to unmute the volume of the audio backtrack. In the example pause setting, if the example audio comparator 410 determines that the energy level of the vocal input exceeds the threshold, the audio comparator 410 instructs the audio backtrack controller 404 to unpause (e.g., restart) the audio backtrack. In some examples, the audio backtrack controller 404 reverses (e.g., rewinds) the audio backtrack when resuming the audio backtrack. The audio backtrack controller 404 may return the audio backtrack to a portion of the audio backtrack that was output normally. For example, if the performer 140 stops singing mid-way through a word or phrase of a song, the audio backtrack controller 404 may restart the audio backtrack at the beginning of the word or phrase.

In some examples, the audio comparator 410 compares one or more waveforms (e.g., a frequency spectrum of the voice signal) of the vocal input to one or more waveforms of the audio backtrack. If the vocal input is sufficiently similar to the audio backtrack (e.g., where the sufficiency is defined by comparing one or more thresholds), the audio backtrack is output by the audio backtrack controller 404. If the vocal input is not sufficiently similar to the audio backtrack (e.g., the performer 104 is singing the wrong song), the audio backtrack is not output by the backtrack controller 404 (e.g., the audio backtrack is muted and the vocals are output to the audience).

In some examples, if the example audio comparator 410 determines that the audio backtrack is to be manipulated by the audio backtrack controller 404, the example audio comparator 410 outputs an indication of the manipulation to an audio monitor (e.g., the audio monitor 112 of FIG. 1). Outputting an indication of the manipulation enables a user (e.g., a producer of a performance) to alter a presentation of the performance based on whether the audio controller 102 is manipulating the audio backtracks. For example, the audio comparator 410 may output an indication that the audio backtrack is to be muted and/or paused to allow the producer to present a commercial and/or to show a video feed from a different camera (e.g., to cut away from video of the performer 104 and to video of the audience) during a television broadcast. By providing an indication that the example audio controller 102 is manipulating audio backtracks, the example audio comparator 410 enables a user to take actions in an attempt to further reduce (e.g., minimize) an audience perception that the performer 104 is not singing. In some examples, outputting an indication that the example audio controller 102 is to manipulate audio backtracks causes the audio monitor 112 to generate a control signal to cause a camera to activate (e.g., to cause a particular camera video feed to be broadcast) or to cause a commercial to be broadcast.

While an example manner of implementing the example audio controller 102 has been illustrated in FIGS. 1 and 4 to control audio playback, one or more of the elements, processes and/or devices illustrated in FIGS. 1 and 4 may be combined, divided, re-arranged, omitted, eliminated and/or implemented in any other way. Further, the example voice controller 402, the example audio backtrack controller 404, the example setting controller 406, the example database 408, the example audio comparator 410, and/or, more generally, the example audio controller 102 of FIGS. 1 and 4 may be implemented by hardware, software, firmware and/or any combination of hardware, software and/or firmware. Thus, for example, any of the example voice controller 402, the example audio backtrack controller 404, the example setting controller 406, the example database 408, the example audio comparator 410, and/or, more generally, the example audio controller 102 of FIGS. 1 and 4 could be implemented by one or more circuit(s), programmable processor(s), application specific integrated circuit(s) (ASIC(s)), programmable logic device(s) (PLD(s)), microprocessor(s), hardware processor(s), and/or field programmable logic device(s) (FPLD(s)), etc. When any of the system or apparatus claims of this patent are read to cover a purely software and/or firmware implementation, at least one of the example voice controller 402, the example audio backtrack controller 404, the example setting controller 406, the example database 408, the example audio comparator 410, and/or, more generally, the example audio controller 102 of FIGS. 1 and 4 are hereby expressly defined to include a tangible computer readable storage medium such as a memory, DVD, CD, Blu-ray disc, etc. storing the software and/or firmware. Further still, the example audio controller 102 of FIGS. 1 and 4 may include one or more elements, processes and/or devices in addition to, or instead of, those illustrated in FIGS. 1 and 4, and/or may include more than one of any or all of the illustrated elements, processes and devices.

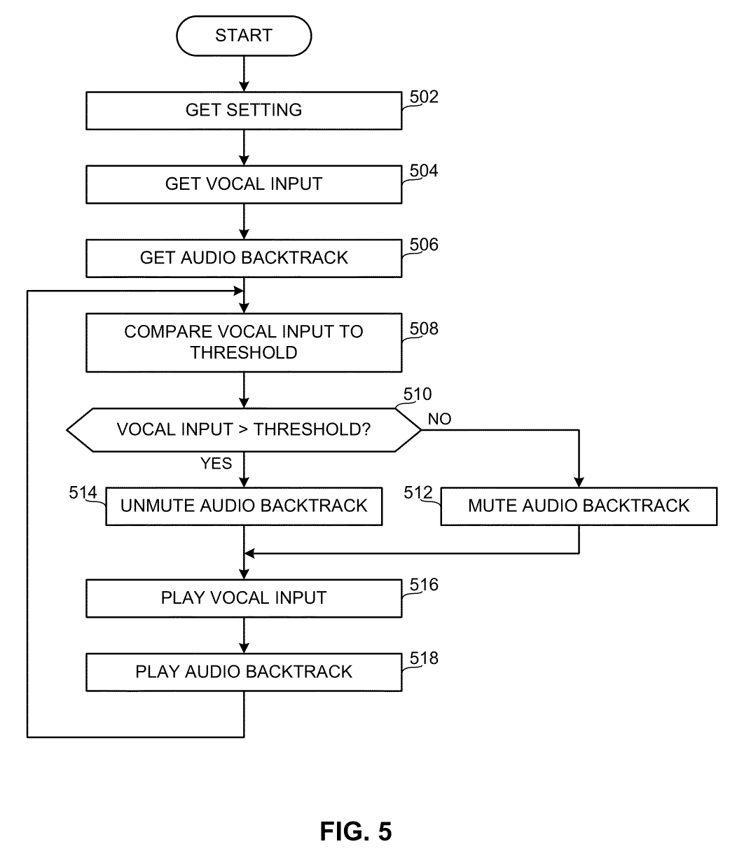

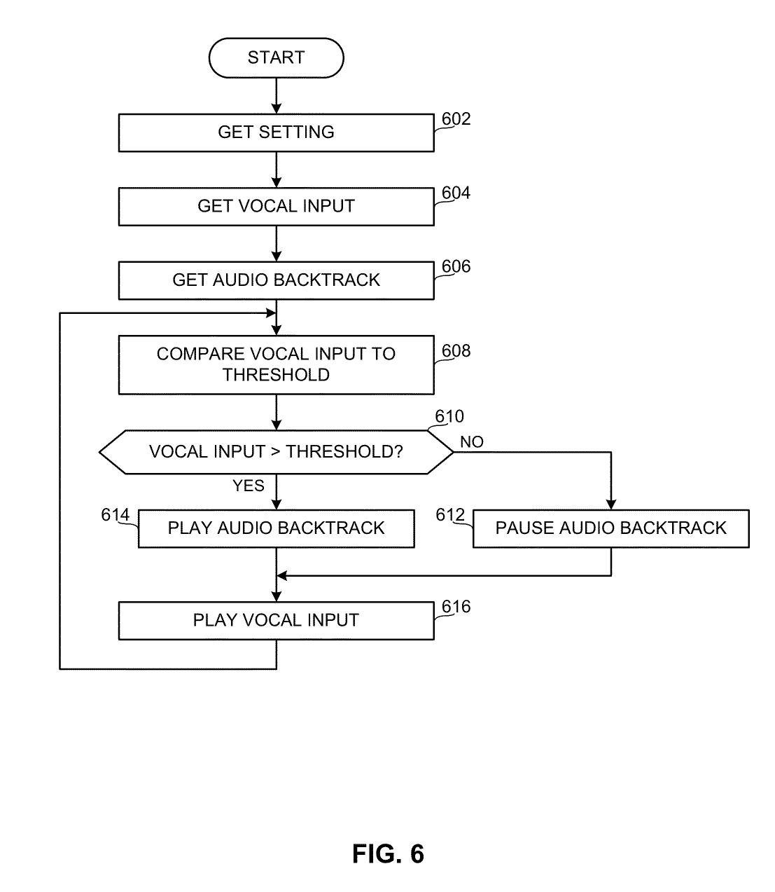

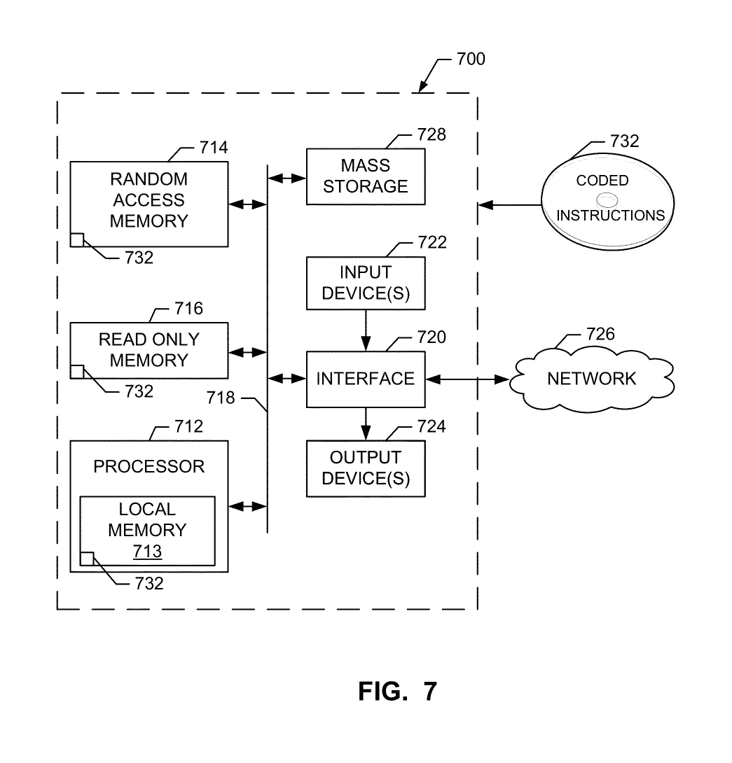

FIGS. 5 and 6 are flowcharts representative of example machine readable instructions for implementing the example audio controller 102 of FIGS. 1 and 4. In the example flowchart of FIGS. 5 and 6, the machine readable instructions comprise program(s) for execution by a processor such as the processor 712 shown in the example computer 700 discussed below in connection with FIG. 7. The program(s) may be embodied in software stored on a tangible computer readable storage medium such as a CD-ROM, a floppy disk, a hard drive, a digital versatile disk (DVD), a Blu-ray disk, or a memory associated with the processor 712, but the entire program and/or parts thereof could alternatively be executed by a device other than the processor 712 and/or embodied in firmware or dedicated hardware. Further, although the example program(s) is described with reference to the flowcharts illustrated in FIGS. 5 and 6, many other methods of implementing the example audio controller 102 of FIGS. 1 and 4 may alternatively be used. For example, the order of execution of the blocks may be changed, and/or some of the blocks described may be changed, eliminated, or combined.

As mentioned above, the example processes of FIGS. 5 and 6 may be implemented using coded instructions (e.g., computer readable instructions) stored on a tangible computer readable storage medium such as a hard disk drive, a flash memory, a read-only memory (ROM), a compact disk (CD), a digital versatile disk (DVD), a cache, a random-access memory (RAM) and/or any other storage device or storage disc in which information is stored for any duration (e.g., for extended time periods, permanently, brief instances, for temporarily buffering, and/or for caching of the information). As used herein, the term tangible computer readable storage medium is expressly defined to include any type of computer readable storage device and/or storage disc and to exclude propagating signals. Additionally or alternatively, the example processes of FIGS. 5 and 6 may be implemented using coded instructions (e.g., computer readable instructions) stored on a non-transitory computer readable storage medium such as a hard disk drive, a flash memory, a read-only memory, a compact disk, a digital versatile disk, a cache, a random-access memory and/or any other storage media in which information is stored for any duration (e.g., for extended time periods, permanently, brief instances, for temporarily buffering, and/or for caching of the information). As used herein, the term non-transitory computer readable storage medium is expressly defined to include any type of computer readable storage device and/or disk and to exclude propagating signals. As used herein, when the phrase “at least” is used as the transition term in a preamble of a claim, it is open-ended in the same manner as the term “comprising” is open ended. Thus, a claim using “at least” as the transition term in its preamble may include elements in addition to those expressly recited in the claim.

The example program of FIG. 5 illustrates an example mute setting implemented by the audio controller 102 of FIGS. 1 and 4. Initially, the example mute setting is set at the example setting controller 406 to determine how audio backtracks are to be output in response to vocal inputs from the input 106 of FIG. 1 (block 502). As described above, if the performer 104 stops singing or stops singing at a threshold audio level, the example audio controller 102 may mute the volume of the audio backtrack, but allows the audio backtrack to continue to progress (e.g., play).

The example voice controller 402 and the example audio comparator 410 receive vocal input from the performer 104 via the microphone 106 (block 504). The example audio backtrack controller 404 retrieves and/or otherwise receives a corresponding audio backtrack from the audio backtrack source 108 (block 506).

The example audio comparator 410 compares the vocal input to one or more thresholds provided by the setting controller 406 in accordance with the particular setting selected by the performer 104 and/or other user or in a default setting (block 508). The threshold specifies a particular energy level to be met or exceeded by the vocal input to allow audio backtracking to be played as normal, without manipulation (e.g., without being muted). The example audio comparator 410 compares an energy level of the vocal input to the threshold (block 510). If the audio comparator 410 determines that the energy level of the vocal input does not exceed the threshold (block 510), the audio comparator 410 instructs the audio backtrack controller 404 to suppress an output of the audio backtrack (e.g., to mute the volume of the audio backtrack) (block 512) and control proceeds to block 516. On the other hand, if the audio comparator 410 determines that the energy level of the vocal input exceeds the threshold (block 510), the audio comparator 410 instructs the audio backtrack controller 404 to unmute the volume of the audio backtrack (block 514).

The example voice controller 402 plays (e.g., outputs) the vocal input via the speakers 110 (block 516). Additionally, the example audio backtrack controller 404 plays (e.g., outputs) the audio backtrack via the speakers 110 at a normal or muted volume (e.g., the example audio backtrack controller 404 manipulates the audio backtrack so that the audio backtrack is played at a muted volume) (block 518). Playing the audio backtrack at a muted volume allows the audio backtrack to continue playing, but not at a volume perceivable by an audience. Control returns to block 508 where the vocal input is compared to the threshold.

In the illustrated example of FIG. 6, a pause setting is implemented by the audio controller 102 of FIGS. 1 and 4. Initially, the example pause setting is configured at the example setting controller 406 to determine how audio backtracks are to be output in response to vocal inputs from the input 106 of FIG. 1 (block 602). As described above, if the performer 104 stops singing or stops singing at a threshold audio level, the example audio controller 102 may pause the audio backtrack (e.g., stops the audio backtrack from playing).

The example voice controller 402 and the example audio comparator 410 receive vocal input from the performer 104 via the microphone 106 (block 604). The example audio backtrack controller 404 retrieves and/or otherwise receives a corresponding audio backtrack from the audio backtrack source 108 (block 606).

The example audio comparator 410 compares the vocal input to one or more thresholds provided by the setting controller 406 in accordance with the particular setting selected by the performer 104 and/or other user or in a default setting (block 608). The threshold specifies a particular energy level to be met or exceeded by the vocal input to allow audio backtracking to be played as normal, without manipulation (e.g., without being paused). The example audio comparator 410 compares an energy level of the vocal input to the threshold (block 610). If the audio comparator 410 determines that the energy level of the vocal input does not exceed the threshold (block 610), the audio comparator 410 instructs the audio backtrack controller 404 to pause the audio backtrack (block 612) and control proceeds to block 616. To pause the audio backtrack, the audio backtrack controller 404 controls (e.g., stops) a temporal pointer associated with the audio backtrack. On the other hand, if the audio comparator 410 determines that the energy level of the vocal input exceeds the threshold (block 610), the audio comparator 410 instructs the audio backtrack controller 404 to play (e.g., output) the audio backtrack via the speakers 110 (block 614). The example voice controller 402 plays (e.g., outputs) the vocal input via the speakers 110 (block 616). Control returns to block 608 where the vocal input is compared to the threshold.

FIG. 7 is a block diagram of an example processor platform 700 capable of executing the instructions of FIGS. 5 and/or 6 to implement the example audio controller 102 of FIGS. 1 and/or 4. The processor platform 700 can be, for example, a server, a personal computer, an Internet appliance, a DVD player, a CD player, a Blu-ray player, a gaming console, a personal video recorder, a mobile device (e.g., a smart phone, a tablet, etc.), a printer, or any other type of computing device.

The processor platform 700 of the instant example includes a processor 712. As used herein, the term “processor” refers to a logic circuit capable of executing machine readable instructions. For example, the processor 712 can be implemented by one or more microprocessors or controllers from any desired family or manufacturer.

The processor 712 includes a local memory 713 (e.g., a cache) and is in communication with a main memory including a volatile memory 714 and a non-volatile memory 716 via a bus 718. The volatile memory 714 may be implemented by Synchronous Dynamic Random Access Memory (SDRAM), Dynamic Random Access Memory (DRAM), RAMBUS Dynamic Random Access Memory (RDRAM) and/or any other type of random access memory device. The non-volatile memory 716 may be implemented by flash memory and/or any other desired type of memory device. Access to the main memory 714, 716 is controlled by a memory controller.

The processor platform 700 also includes an interface circuit 720. The interface circuit 720 may be implemented by any type of interface standard, such as an Ethernet interface, a universal serial bus (USB), and/or a PCI express interface.

One or more input devices 722 are connected to the interface circuit 720. The input device(s) 722 permit a user to enter data and commands into the processor 712. The input device(s) can be implemented by, for example, a keyboard, a mouse, a touchscreen, a track-pad, a trackball, isopoint and/or a voice recognition system.

One or more output devices 724 are also connected to the interface circuit 720. The output devices 724 can be implemented, for example, by display devices (e.g., a liquid crystal display, a cathode ray tube display (CRT), a printer and/or speakers). The interface circuit 720, thus, typically includes a graphics driver card.

The interface circuit 720 also includes a communication device such as a modem or network interface card to facilitate exchange of data with external computers via a network 726 (e.g., an Ethernet connection, a digital subscriber line (DSL), a telephone line, coaxial cable, a cellular telephone system, etc.).

The processor platform 700 also includes one or more mass storage devices 728 for storing software and data. Examples of such mass storage devices 728 include floppy disk drives, hard drive disks, compact disk drives and digital versatile disk (DVD) drives.

The coded instructions 732 of FIG. 7 may be stored in the mass storage device 728, in the volatile memory 714, in the non-volatile memory 716, and/or on a removable storage medium such as a CD or DVD.

Example methods for audio backtracking control include comparing an audio input value associated with an audio input to a threshold, the audio input to be synchronized with an audio backtrack, suppressing an output of the audio backtrack when the audio input value is below the threshold, and controlling a temporal pointer associated with the audio backtrack during a period of time in which the audio input value is below the threshold. In some disclosed example methods, the threshold is associated with an energy level of the audio input. In some example disclosed methods, the threshold is associated with a decibel level of the audio input. In some example disclosed methods, the threshold is associated with a similarity level of a waveform of the audio input and a waveform of the audio backtrack. In some disclosed example methods, suppressing the output of the audio backtrack comprises lowering a volume of the audio backtrack. Some example methods include outputting the audio backtrack in conjunction with the audio input. In some disclosed example methods, controlling the temporal pointer associated with the audio backtrack comprises pausing the audio backtrack. Some example methods include outputting the audio backtrack in conjunction with the audio input. In some disclosed example methods the audio input is output in conjunction with the audio backtrack. In some disclosed example methods, the audio backtrack is output instead of the audio input.

Example apparatus for audio backtracking control include a comparator to compare an audio input value associated with an audio input to a threshold, the audio input to be synchronized with an audio backtrack, and a backtrack controller to suppress an output of the audio backtrack when the audio input value is below the threshold, and control a temporal pointer associated with the audio backtrack during a period of time in which the audio input value is below the threshold. In some disclosed example apparatus, the threshold is associated with an energy level of the audio input. In some disclosed example apparatus, the threshold is associated with a decibel level of the audio input. In some disclosed example apparatus, the threshold is associated with a similarity level of a waveform of the audio input and a waveform of the audio backtrack. In some disclosed example apparatus, to suppress the output of the audio backtrack, the backtrack controller is to lower a volume of the audio backtrack. In some disclosed example apparatus, the backtrack controller is to output the audio backtrack in conjunction with the audio input. In some disclosed example apparatus, to control the temporal pointer associated with the audio backtrack, the backtrack controller is to pause the audio backtrack. In some disclosed example apparatus, the backtrack controller is to output the audio backtrack in conjunction with the audio input. In some disclosed example apparatus, the backtrack controller is to output the audio backtrack in conjunction with the audio input. In some disclosed example apparatus, the backtrack controller is to output the audio backtrack instead of the audio input.

Example tangible machine readable storage media comprise instructions that, when executed, cause a machine to at least compare an audio input value based on an audio input to a threshold, the audio input to be synchronized with an audio backtrack, suppress an output of the audio backtrack when the audio input value is below the threshold, and control a temporal pointer associated with the audio backtrack during a period of time in which the audio input value is below the threshold. In some disclosed example machine readable storage media, the threshold defines an energy level of the audio input. In some disclosed example machine readable storage media, the threshold defines a decibel level of the audio input. In some disclosed example machine readable storage media, the threshold is associated with a similarity level of a waveform of the audio input and a waveform of the audio backtrack. In some disclosed example machine readable storage media, the instructions, when executed, cause the machine to suppress the output of the audio backtrack by lowering a volume of the audio backtrack. In some disclosed example machine readable storage media, the instructions, when executed, cause the machine to output the audio backtrack in conjunction with the audio input. In some disclosed example machine readable storage media, the instructions, when executed, cause the machine to control the temporal pointer associated with the audio backtrack by pausing the audio backtrack. In some disclosed example machine readable storage media, the instructions, when executed, cause the machine to output the audio input in conjunction with the audio backtrack. In some disclosed example machine readable storage media, the instructions, when executed, cause the machine to output the audio backtrack instead of the audio input.

Although certain example apparatus, methods, and articles of manufacture have been disclosed herein, the scope of coverage of this patent is not limited thereto. On the contrary, this patent covers all apparatus, methods, and articles of manufacture fairly falling within the scope of the claims of this patent.

What is claimed is:

1. A method comprising:
comparing an audio input value associated with an audio input to a threshold, the audio input to be synchronized with an audio backtrack;
suppressing an output of the audio backtrack when the audio input value is below the threshold; and
controlling a temporal pointer associated with the audio backtrack during a period of time in which the audio input value is below the threshold.

2. The method of claim 1, wherein the threshold is associated with an energy level of the audio input.

3. The method of claim 1, wherein the threshold is associated with a decibel level of the audio input.

4. The method of claim 1, wherein the threshold is associated with a similarity level of a waveform of the audio input and a waveform of the audio backtrack.

5. The method of claim 1, wherein suppressing the output of the audio backtrack comprises lowering a volume of the audio backtrack.

6. The method of claim 5, further comprising outputting the audio backtrack in conjunction with the audio input.

7. The method of claim 1, wherein controlling the temporal pointer associated with the audio backtrack comprises pausing the audio backtrack.

8. The method of claim 7, further comprising outputting the audio backtrack in conjunction with the audio input.

9. The method of claim 1, wherein the audio input is output in conjunction with the audio backtrack.

10. The method of claim 1, wherein the audio backtrack is output instead of the audio input.

11. An apparatus comprising:
a comparator to compare an audio input value associated with an audio input to a threshold, the audio input to be synchronized with an audio backtrack; and
a backtrack controller to:
suppress an output of the audio backtrack when the audio input value is below the threshold; and
control a temporal pointer associated with the audio backtrack during a period of time in which the audio input value is below the threshold.

12. The apparatus of claim 11, wherein the threshold is associated with an energy level of the audio input.

13. The apparatus of claim 11, wherein the threshold is associated with a decibel level of the audio input.

14. The apparatus of claim 11, wherein the threshold is associated with a similarity level of a waveform of the audio input and a waveform of the audio backtrack.

15. The apparatus of claim 11, wherein to suppress the output of the audio backtrack, the backtrack controller is to lower a volume of the audio backtrack.

16. The apparatus of claim 15, wherein the backtrack controller is to output the audio backtrack in conjunction with the audio input.

17. The apparatus of claim 11, wherein to control the temporal pointer associated with the audio backtrack, the backtrack controller is to pause the audio backtrack.

18. The apparatus of claim 17, wherein the backtrack controller is to output the audio backtrack in conjunction with the audio input.

19. The apparatus of claim 11, wherein the backtrack controller is to output the audio backtrack in conjunction with the audio input.

20. The apparatus of claim 11, wherein the backtrack controller is to output the audio backtrack instead of the audio input.

21. A tangible machine readable storage medium comprising instructions that, when executed, cause a machine to at least:
compare an audio input value based on an audio input to a threshold, the audio input to be synchronized with an audio backtrack;
suppress an output of the audio backtrack when the audio input value is below the threshold; and
control a temporal pointer associated with the audio backtrack during a period of time in which the audio input value is below the threshold.

22. The machine readable storage medium of claim 21, wherein the threshold defines an energy level of the audio input.

23. The machine readable storage medium of claim 21, wherein the threshold defines a decibel level of the audio input.

24. The machine readable storage medium of claim 21, wherein the threshold is associated with a similarity level of a waveform of the audio input and a waveform of the audio backtrack.

25. The machine readable storage medium of claim 21, wherein the instructions, when executed, cause the machine to suppress the output of the audio backtrack by lowering a volume of the audio backtrack.

26. The machine readable storage medium of claim 25, wherein the instructions, when executed, cause the machine to output the audio backtrack in conjunction with the audio input.

27. The machine readable storage medium of claim 21, wherein the instructions, when executed, cause the machine to control the temporal pointer associated with the audio backtrack by pausing the audio backtrack.

28. The machine readable storage medium of claim 21, wherein the instructions, when executed, cause the machine to output the audio input in conjunction with the audio backtrack.

29. The machine readable storage medium of claim 21, wherein the instructions, when executed, cause the machine to output the audio backtrack instead of the audio input.
